(19) United States
(12) Patent Application Publication
(10) Pub. No.: US 2006/0239085 A1
(43) Pub. Date: Oct. 26, 2006

(54) Dynamic shift register

(75) Inventors: Hong Gi Wu, Miao-Li (TW); Jia-Pang Pang, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/111,341

(22) Filed: Apr. 20, 2005

(30) Foreign Application Priority Data
Apr. 20, 2005 (TW) 93110939

(51) Int. Cl. G11C 7/00

(52) U.S. Cl. 365/189.12

(57) ABSTRACT

A dynamic shift register includes a first stage (21) and a second stage (22). The first stage includes a logical inputting port (201), a first retaining circuit (231), and a first transmitting gate (211). The first transmitting gate includes an input connected to the logical inputting port, and an output connected to the first retaining circuit. The second stage includes a logical outputting port (205), a second retaining circuit (232), and a second transmitting gate (212). The second transmitting gate includes an input connected to the output of the first transmitting gate, and an output connected to the logical outputting port and the second retaining circuit. In a cycle, after the clock signal and the complementary clock signal are stopped, the dynamic shift register can stably retain the logical signal.

### FIELD OF THE INVENTION

The present invention relates to shift registers used in electrical driving circuits of electronic equipment such as liquid crystal displays, and particularly to dynamic shift registers.

### BACKGROUND

Generally, driving circuits for liquid crystal displays include source driving circuits and gate driving circuits. The source driving circuits are used for controlling a gray level of each pixel, and the gate driving circuits are used for controlling scanning of each pixel. The source driving circuits and gate driving circuits use shift registers for core circuits. Each shift register ordinarily comprises multistage circuits orderly connected, and can delay and store binary signals.

During operation of the shift register, each stage thereof at any moment contains a binary digital bit of information represented by a relatively high or low voltage level at a node in the stage. Each such bit of information is retained in its corresponding stage for a cycle of a clock pulse, which drives all the various stages simultaneously, and each stage feeds its information bit periodically (at the termination of each clock cycle) to the next succeeding stage. Thus, in response to a sequence of these clock pulses, each bit of information sequentially passes through the entire shift register from an initial input register stage to a final output register stage. During each clock cycle, moreover, the input stage receives a fresh bit of information, while the output stage shifts and delivers its bit of information to a utilization device.

Shift registers are generally classified as static registers and dynamic registers respectively. In a static shift register, all the information present at any moment in the register is stored and output. However, in a dynamic shift register, the information in the various stages at any moment is irretrievably lost in case the clock pulse voltages temporarily stop. Thus, static shift registers have an advantage over dynamic shift registers insofar as static shift registers retain information during driving clock stoppages.

On the other hand, static shift registers have more semiconductor circuit elements per stage, and hence require more space on the semiconductor wafer (chip) in which the shift register circuit is built. For example, each stage of a static shift register circuit which is driven by a two-phase clock ordinarily requires four electrical transmission gate elements plus four electrical inverter elements; whereas a two-phase dynamic register requires only two such gates plus two such inverters. This added semiconductor wafer space requirement of static shift register circuits presents a serious problem, because in general manufacturing yields in the semiconductor art decrease sharply with increased semiconductor wafer area.

Referring to FIG. 9, a classic dynamic shift register 100 includes a first stage 11 and a second stage 12. The first stage 11 includes a logical inputting port 101, a first transmitting gate 111, and a first phase inverter 121. The second stage 12 includes a second transmitting gate 112, a second phase inverter 122, and a logical outputting port 105. The first transmitting gate 111 includes an input, an output, a first P-type insulated gate field effect transistor (P-IGFET) 181, and a first N-type insulated gate field effect transistor (N-IGFET) 171. The second transmitting gate 112 includes an input, an output, a second P-type insulated gate field effect transistor (P-IGFET) 182, and a second N-type insulated gate field effect transistor (N-IGFET) 172.

The logical inputting port 101 is connected to the input of the first transmitting gate 111. The output of the first transmitting gate 111 is connected to an input of the first phase inverter 121. An output of the first phase inverter 121 is connected to the input of the second transmitting gate 112. The output of the second transmitting gate 112 is connected to an input of the second phase inverter 122. An output of the second phase inverter 122 is connected to the logical outputting port 105. In the first transmitting gate 111, a source of the first P-IGFET 181 and a drain of the first N-IGFET 171 are connected to the input of the first transmitting gate 111, and a drain of the first P-IGFET 181 and a source of the first N-IGFET 171 are connected to the output of the first transmitting gate 111. In the second transmitting gate 112, a source of the second P-IGFET 182 and a drain of the second N-IGFET 172 are connected to the input of the second transmitting gate 112, and a drain of the second P-IGFET 182 and a source of the second N-IGFET 172 are connected to the output of the first transmitting gate 112.

During operation of the dynamic shift register 100, a logical signal applied to the logical inputting port 101 may pass through the first transmitting gate 111 and the first phase inverter 121 to the input of the second transmitting gate 112, which occurs when a clock signal CLK is applied to the first P-IGFET 181 and the second N-IGFET 172, and simultaneously a complementary clock signal XCLK is applied to the first N-IGFET 171 and the second P-IGFET 182. Thereafter, the logical signal passes through the second transmitting gate 112 and the second phase inverter 122 to the logical outputting port 105.

In a clock cycle, after the clock signal CLK and the complementary clock signal XCLK are stopped, and the first transmitting gate 111 is off and outputs a floating voltage. The floating voltage is retained by the high resistance of the first phase inverter 121, the first P-IGFET 181, and the first N-IGFET 171. Therefore, the floating voltage output by the first transmitting gate 111 may be affected by other parasitic effects. The second transmitting gate 112 also outputs a floating voltage, which may be also affected by other parasitic effects.

What is needed is a dynamic shift register which can overcome the above-described problems.

### SUMMARY

In one embodiment, a dynamic shift register includes a first stage and a second stage. The first stage includes a logical inputting port, a first retaining circuit and a first transmitting gate, which comprising an input connected to the logical inputting port, and an output connected to the first retaining circuit. The second stage includes a logical outputting port, a second retaining circuit and a second transmitting gate, which comprising an input connected to the output of the first transmitting gate, and an output connected to the logical outputting port and the second retaining circuit.

Because the first stage includes a first retaining circuit and the second stage includes a second retaining circuit, during operation of the dynamic shift register, a logical signal applied to the logical inputting port may be retained by the first and second circuits after a clock signal and a complementary clock signal applied to the first and second transmitting gates are stopped in a cycle. Therefore, in a cycle, after the clock signal and the complementary clock signal are stopped, the dynamic shift register can stably retain the logical signal.

Other objects, advantages, and novel features of embodiments of the present invention will become more apparent from the following detailed description when taken in conjunction with the accompanying drawings, in which:

### BRIEF DESCRIPTION OF THE DRAWINGS

FIG. 1 is a circuit diagram of a dynamic shift register according to a first embodiment of the present invention;

FIGS. 2, 3, and 4 are operating timing diagrams of the dynamic shift register of FIG. 1;

FIG. 5 is a circuit diagram of a dynamic shift register according to a second embodiment of the present invention;

FIGS. 6, 7, and 8 are operating timing diagrams of the dynamic shift register of FIG. 5; and

FIG. 9 is a circuit diagram of a conventional dynamic shift register.

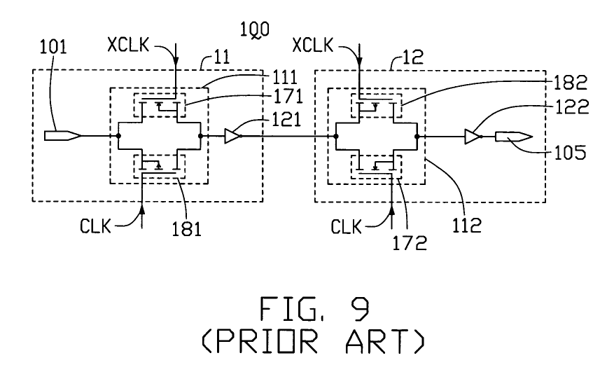

### DETAILED DESCRIPTION OF PREFERRED EMBODIMENTS

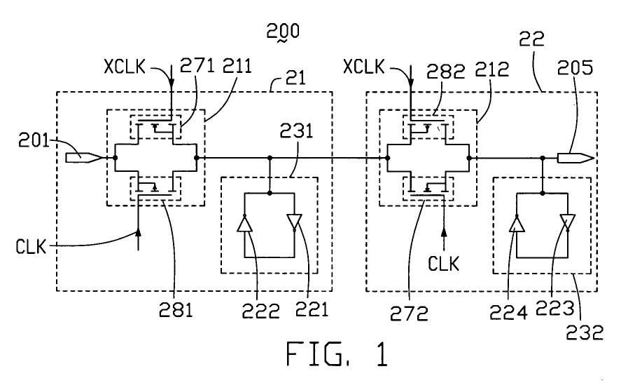

Referring to FIG. 1, a dynamic shift register 200 according to a first embodiment of the present invention includes a first stage 21 and a second stage 22. The first stage 21 includes a logical inputting port 201, a first retaining circuit 231, and a first transmitting gate 211. The first transmitting gate 211 comprises an input, an output, a first P-IGFET 281, and a first N-IGFET 271. The second stage 22 includes a logical outputting port 205, a second retaining circuit 232, and a second transmitting gate 212. The second transmitting gate 212 comprises an input, an output, a second P-IGFET 282, and a second N-IGFET 272. The first retaining circuit 231 includes a first phase inverter 221 and a second phase inverter 222. The second retaining circuit 232 includes a third phase inverter 223 and a fourth phase inverter 224.

The logical inputting port 201 is connected to the input of the first transmitting gate 211. The output of the first transmitting gate 211 is connected to the input of the second transmitting gate 212. The output of the second transmitting gate 212 is connected to the logical outputting port 205. The first retaining circuit 231 is connected to the output of the first transmitting gate 211. The second retaining circuit 232 is connected to the output of the second transmitting gate 212.

In the first transmitting gate 211, a source of the first P-IGFET 281 and a drain of the first N-IGFET 271 are connected to the input of the first transmitting gate 211, and a drain of the first P-IGFET 281 and a source of the first N-IGFET 271 are connected to the output of the first transmitting gate 211. In the second transmitting gate 212, a source of the second P-IGFET 282 and a drain of the second N-IGFET 272 are connected to the input of the second transmitting gate 212, and a drain of the second P-IGFET 282 and a source of the second N-IGFET 272 are connected to the output of the second transmitting gate 212.

In the first retaining circuit 231, an output of the first phase inverter 221 is connected to an input of the second phase inverter 222, and an input of the first phase inverter 221 and an output of the second phase inverter 222 are connected to the output of the first transmitting gate 211. In the second retaining circuit 232, an output of the third phase inverter 223 is connected to an input of the fourth phase inverter 224, and an input of the third phase inverter 223 and an output of the fourth phase inverter 224 are connected to the output of the second transmitting gate 212.

During operation of the dynamic shift register 200, a logical signal applied to the logical inputting port 201 may orderly pass through the first transmitting gate 211, the first retaining circuit 231, the second transmitting gate 212 and the second retaining circuit 232 to the logical outputting port 205, when a clock signal CLK and a complementary clock signal XCLK are applied to each of the first and second transmitting gates 211, 212. The first and second retaining circuits 231, 232 can retain the logical signal.

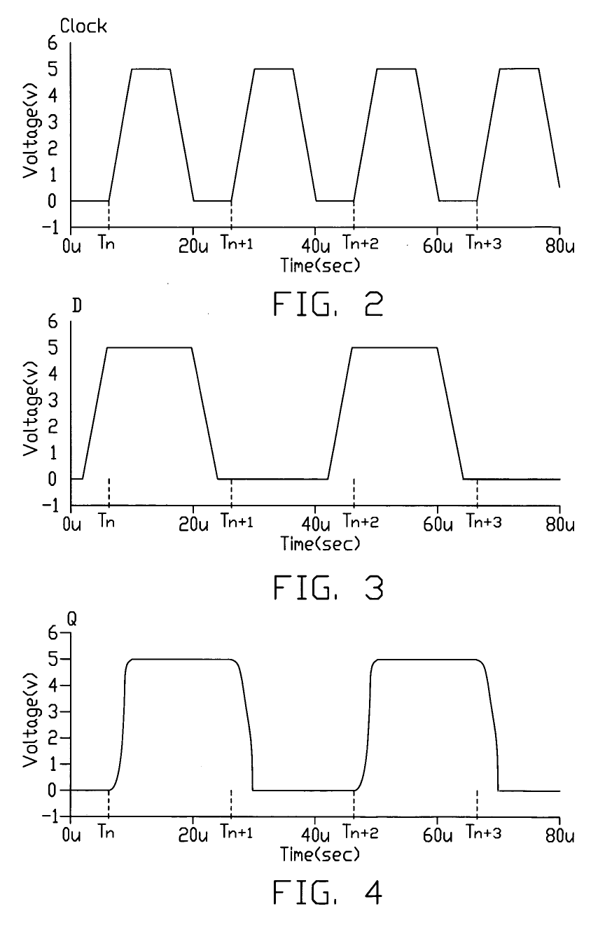

Referring to FIGS. 2, 3, and 4, Clock denotes a clock signal applied to the first and second transmitting gates 211, 212. D denotes a logical signal applied the logical inputting port 201. Q denotes a logical signal output from the logical outputting port 205. Before time Tₙ, the logical signal D is at a high potential, and the logical signal Q is at a low potential. At time Tₙ, the first and second transmitting gates 211, 212 are on in sync with an advancing edge of the clock signal Clock, and the logical signal D is applied to the first and second transmitting gates 211, 212, so that the logical signal Q changes from the low potential to the high potential and retains the high potential.

Before time Tₙ₊₁, the logical signal D is the low potential, and the logical signal Q is the high potential. At time Tₙ₊₁, the first and second transmitting gates 211, 212 are on in sync with an advancing edge of the clock signal Clock, and the logical signal D is applied to the first and second transmitting gates 211, 212, so that the logical signal Q changes from the high potential to the low potential and retains the low potential.

Before time Tₙ₊₂, the logical signal D is the high potential, and the logical signal Q is the low potential. At time Tₙ₊₂, the first and second transmitting gates 211, 212 are on in sync with an advancing edge of the clock signal Clock, and the logical signal D is applied to the first and second transmitting gates 211, 212, so that the logical signal Q changes from the low potential to the high potential and retains the high potential.

Before time Tₙ₊₃, the logical signal D is the low potential, and the logical signal Q is the high potential. At time Tₙ₊₃, the first and second transmitting gates 211, 212 are on in sync with an advancing edge of the clock signal Clock, and the logical signal D is applied to the first and second transmitting gates 211, 212, so that the logical signal Q changes from the high potential to the low potential and retains the low potential.

According to the above description, when the clock signal Clock is stopped, the logical signal Q output from the logical outputting port 205 can be retained. That is, in each cycle, the dynamic shift register can stably retain the logical signal applied the logical inputting port 201. However, to retain the logical signal applied the logical inputting port 201 after the clock signal Clock is stopped, it is necessary to increase the consumption of power, and this is not desired.

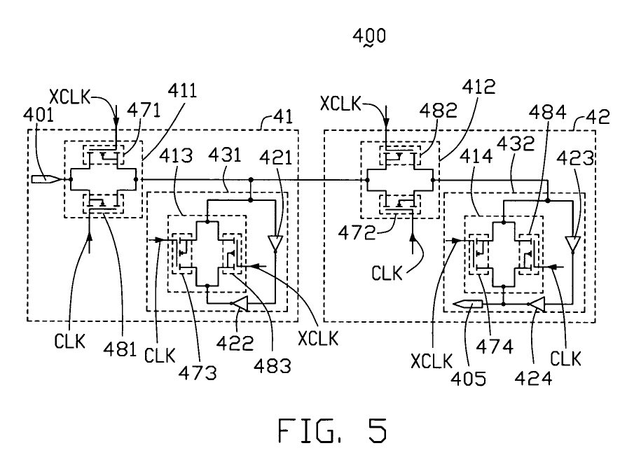

To solve the above need for increasing the consumption of power, a dynamic shift register according to a second embodiment is provided. Referring to FIG. 5, the dynamic shift register 400 includes a first stage 41 and a second stage 42. The first stage 41 includes a logical inputting port 401, a first retaining circuit 431, and a first transmitting gate 411. The first transmitting gate 411 comprises an input, an output, a first P-IGFET 481, and a first N-IGFET 471. The second stage 42 includes a logical outputting port 405, a second retaining circuit 432, and a second transmitting gate 412. The second transmitting gate 412 comprises an input, an output, a second P-IGFET 482, and a second N-IGFET 472. The first retaining circuit 431 includes a first phase inverter 421, a second phase inverter 422, and a third transmitting gate 413. The second retaining circuit 432 includes a third phase inverter 423, a fourth phase inverter 424, and a fourth transmitting gate 414. The third transmitting gate 413 includes an input, an output, a third P-IGFET 483, and a third N-IGFET 473. The fourth transmitting gate 414 includes an input, an output, a fourth P-IGFET 484, and a fourth N-IGFET 474.

The logical inputting port 401 is connected to the input of the first transmitting gate 411. The output of the first transmitting gate 411 is connected to an input of the second transmitting gate 412 and the first retaining circuit 431. The second retaining circuit 432 is connected to the output of the second transmitting gate 412 and the logical outputting port 205.

In the first transmitting gate 411, a source of the first P-IGFET 481 and a drain of the first N-IGFET 471 are connected to the input of the first transmitting gate 411, and a drain of the first P-IGFET 481 and a source of the first N-IGFET 471 are connected to the output of the first transmitting gate 411. In the second transmitting gate 412, a source of the second P-IGFET 482 and a drain of the second N-IGFET 472 are connected to the input of the second transmitting gate 412, and a drain of the second P-IGFET 482 and a source of the second N-IGFET 472 are connected to the output of the second transmitting gate 412.

In the first retaining circuit 431, an output of the first phase inverter 421 is connected to an input of the second phase inverter 422, an output of the second phase inverter 422 is connected to the input of the third transmitting gate 413, and an input of the first phase inverter 421 and the output of the third transmitting gate 413 are connected to the output of the first transmitting gate 411. In the second retaining circuit 432, an output of the third phase inverter 423 is connected to an input of the fourth phase inverter 424, an output of the fourth phase inverter 424 is connected to the input of the fourth transmitting gate 414, and an input of the third phase inverter 423 and the output of the fourth transmitting gate 414 are connected to the output of the second transmitting gate 412.

In the third transmitting gate 413, a source of the third P-IGFET 483 and a drain of the third N-IGFET 473 are connected to the input of the third transmitting gate 413, and a drain of the third P-IGFET 483 and a source of the third N-IGFET 473 are connected to the output of the third transmitting gate 413. In the fourth transmitting gate 414, a source of the fourth P-IGFET 484 and a drain of the fourth N-IGFET 474 are connected to the input of the fourth transmitting gate 414, and a drain of the fourth P-IGFET 484 and a source of the fourth N-IGFET 474 are connected to the output of the fourth transmitting gate 414.

During operation of the dynamic shift register 400, a logical signal applied to the logical inputting port 401 may orderly pass through the first transmitting gate 411, the first retaining circuit 431, the second transmitting gate 412 and the second retaining circuit 432 to the logical outputting port 205, when a clock signal CLK and a complementary clock signal XCLK are applied to each of the first, second, third, and fourth transmitting gates 411, 412, 413 and 414. The first and second retaining circuits 431, 432 can retain the logical signal.

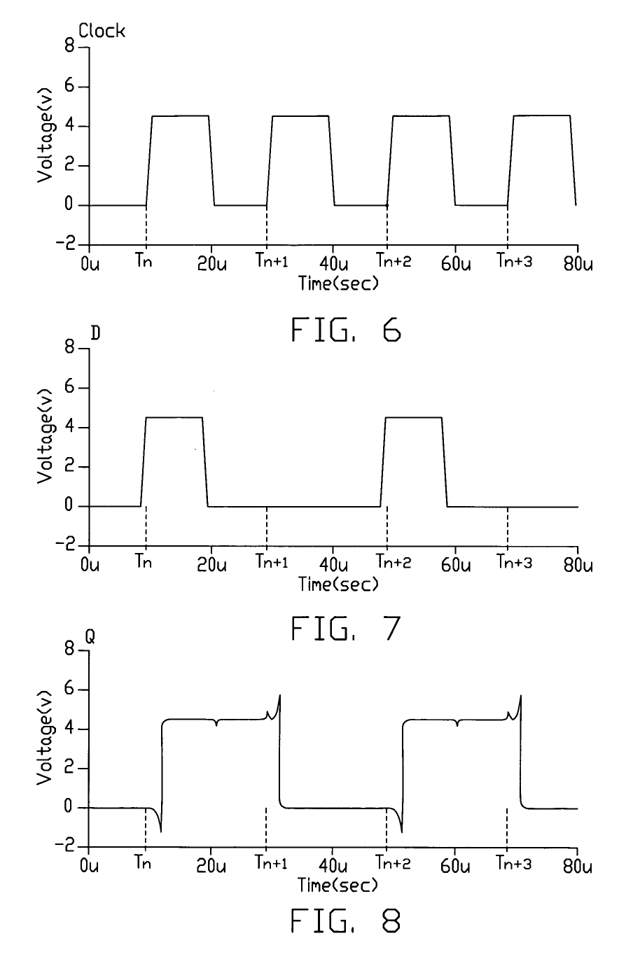

Referring to FIGS. 6, 7, and 8, Clock denotes a clock signal applied to the first, second, third, and fourth transmitting gates 411, 412, 413 and 414. D denotes a logical signal applied the logical inputting port 401. Q denotes a logical signal output from the logical outputting port 405.

Before time Tₙ, the logical signal D is at a high potential, and the logical signal Q is at a low potential. At time Tₙ, the first, second, third, and fourth transmitting gates 411, 412, 413 and 414 are on in sync with an advancing edge of the clock signal Clock. Because of the third and fourth transmitting gates 413, 414 being on, the first and second retaining circuits 431, 432 discharge to the output of the second transmitting gate 412. At the same time, because of the first and second transmitting gates 411, 412 being on, the first and second transmitting gates 411, 412 charge to the output of the second transmitting gate 412. Therefore, the low potential of the output of the second transmitting gate 412 changes to a high potential after falling for a short time. Then the potential of the output of the second transmitting gate 412 passes through the third phase inverter 423 and the fourth phase inverter 424 to the logical outputting port 405. Consequently, the low potential of the logical signal Q changes to a high potential after falling for a short time.

Before time Tₙ₊₁, the logical signal D is at a low potential, and the logical signal Q is at a high potential. At time Tₙ₊₁, the first, second, third, and fourth transmitting gates 411, 412, 413 and 414 are on in sync with an advancing edge of the clock signal Clock. Because of the third and fourth transmitting gates 413, 414 being on, the first and second retaining circuits 431, 432 charge to the output of the second transmitting gate 412. At the same time, because of the first and second transmitting gates 411, 412 being on, the first and second transmitting gates 411, 412 discharge to the output of the second transmitting gate 412. Therefore, the high potential of the output of the second transmitting gate 412 changes to a low potential after advancing for a short time. Then the potential of the output of the second transmitting gate 412 passes through the third phase inverter 423 and the fourth phase inverter 424 to the logical outputting port 405. Consequently, the high potential of the logical signal Q changes to a low potential after advancing for a short time.

In similar fashion, the low potential of the logical signal Q changes to a high potential after falling for a short time at time Tₙ₊₂, and the high potential of the logical signal Q changes to a low potential after advancing for a short time at time Tₙ₊₃.

According to the above description, because of the first retaining circuit 431 including the third transmitting gate 413 and because of the second retaining circuit 432 including the fourth transmitting gate 414, the first and second retaining circuits 431, 432 can charge or discharge to the output of the second transmitting gate 412. The retaining time of the logical signal Q is reduced after the clock signal Clock is stopped. That is, when the clock signal Clock is the low potential, the retaining time of the logical signal Q is reduced. Consequently, the consumption of power of the dynamic shift register 400 is lower than the consumption of power of the dynamic shift register 200.

In an alternative embodiment, the dynamic shift register 200 may include only one of the first retaining circuit 231 and the second retaining circuit 232. In another alternative embodiment, the dynamic shift register 400 may include only one of the third transmitting gate 413 and the fourth transmitting gate 414.

It is to be further understood that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

We claim:

1. A dynamic shift register comprising:
a first stage, comprising a logical inputting port, a first retaining circuit, and a first transmitting gate, the first transmitting gate comprising an input connected to the logical inputting port, and an output connected to the first retaining circuit; and
a second stage, comprising a logical outputting port, a second retaining circuit, and a second transmitting gate, the second transmitting gate comprising an input connected to the output of the first transmitting gate, and an output connected to the logical outputting port and the second retaining circuit.

2. The dynamic shift register as claimed in claim 1, wherein the first retaining circuit comprises a first phase inverter and a second phase inverter, an input of the second phase inverter being connected to an output of the first phase inverter, and an input of the first phase inverter and an output of the second phase inverter being connected to the output of the first transmitting gate.

3. The dynamic shift register as claimed in claim 1, wherein the second retaining circuit comprises a first phase inverter and a second phase inverter, an input of the second phase inverter being connected to an output of the first phase inverter, an input of the first phase inverter and an output of the second phase inverter being connected to the logical outputting port of the second stage.

4. The dynamic shift register as claimed in claim 1, wherein the first and second transmitting gates comprise insulated gate field effect transistors.

5. The dynamic shift register as claimed in claim 1, further comprising an extrinsic loop for controlling the first transmitting gate and the second transmitting gate.

6. The dynamic shift register as claimed in claim 1, wherein the first retaining circuit comprises a first phase inverter, a second phase inverter and a third transmitting gate, an input of the second phase inverter being connected to an output of the first phase inverter, an output of the second phase inverter being connected to an input of the third transmitting gate, and an input of the first phase inverter and an output of the third transmitting gate being connected to the output of the first transmitting gate.

7. The dynamic shift register as claimed in claim 6, further comprising an extrinsic loop for controlling the first, second and third transmitting gates.

8. The dynamic shift register as claimed in claim 1, wherein the second retaining circuit comprises a first phase inverter, a second phase inverter and a third transmitting gate, an input of the second phase inverter being connected to an output of the first phase inverter, an output of the second phase inverter being connected to an input of the third transmitting gate, an input of the first phase inverter and the output of the third transmitting gate being connected to the output of the second transmitting gate.

9. The dynamic shift register as claimed in claim 8, further including an extrinsic loop for controlling the first, second and third transmitting gates.

10. The dynamic shift register as claimed in claim 9, wherein the logical outputting port is connected to the output of the second phase inverter.

11. A dynamic shift register comprising:
a logical inputting port;
a first transmitting gate, comprising an input connected to the logical inputting port, and an output;
a second transmitting gate, comprising an input connected to the output of the
first transmitting gate, and an output;
a logical outputting port; and
a retaining circuit connected to the output of the first transmitting gate.

12. The dynamic shift register as claimed in claim 11, wherein the retaining circuit comprises a first phase inverter and a second phase inverter, an input of the second phase inverter being connected to an output of the first phase inverter, an input of the first phase inverter and an output of the second phase inverter being connected to the output of the first transmitting gate.

13. The dynamic shift register as claimed in claim 11, wherein the retaining circuit comprises a first phase inverter and a second phase inverter, and a third transmitting gate, an input of the second phase inverter being connected to an output of the first phase inverter, an output of the second phase inverter being connected to an input of the third transmitting gate, and an input of the first phase inverter and an output of the third transmitting gate being connected to the output of the first transmitting gate.

14. A dynamic shift register comprising:
a logical inputting port;
a first transmitting gate, comprising an input connected to the logical inputting port, and an output;
a second transmitting gate, comprising an input connected to the output of the first transmitting gate, and an output;
a logical outputting port; and
a retaining circuit connected to the logical outputting port.

15. The dynamic shift register as claimed in claim 14, wherein the retaining circuit comprises a first phase inverter and a second phase inverter, an input of the second phase inverter being connected to an output of the first phase inverter, an input of the first phase inverter and an output of the second phase inverter being connected to the logical outputting port.

16. The dynamic shift register as claimed in claim 14, wherein the retaining circuit comprises a first phase inverter, a second phase inverter and a third transmitting gate, an input of the second phase inverter being connected to an output of the first phase inverter, an output of the second phase inverter being connected to an input of the third transmitting gate, an input of the first phase inverter and the output of the third transmitting gate being connected to the output of the second transmitting gate.
